(19) United States
(12) Patent Application Publication
(10) Pub. No.: US 2012/0161799 A1
(43) Pub. Date: Jun. 28, 2012

(54) FOUR-WIRE MILLIOHMMETER AND PROBE ASSEMBLY THEREOF

(75) Inventors: YUN-SHAN XIAO, Shenzhen City (CN); JIAN-CHUN PAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/076,458

(22) Filed: Mar. 31, 2011

(30) Foreign Application Priority Data
Dec. 25, 2010 (CN) 201010606832.X

(51) Int. Cl. G01R 27/08

(52) U.S. Cl. 324/715

(57) ABSTRACT

An exemplary four-wire milliohmmeter includes a main body and two probe assemblies electrically connected with the main body. Each of the probe assemblies includes two plugs detachably inserted into the main body, a contact member, and two wires each electrically connecting one of the plugs to the contact member. The contact portion of each probe assembly has a needlelike free end for contacting an object.

### BACKGROUND

1. Technical Field

The disclosure generally relates to four-wire milliohmmeters, and more particularly relates to a four-wire milliohmmeter having improved connectors.

2. Description of Related Art

Four-wire milliohmmeters are commonly used in various fields of electronics for measuring relay contact resistance, lead resistance, component solder resistance, switch and socket contact resistance, and so on. The four-wire milliohmmeter typically includes two contact members to contact the object under test. The contact members of a conventional four-wire milliohmmeter are clip-type, which are suitable for easily clipping objects having large areas or volumes. However, clip-type contact members are not able to contact tiny objects, such as tiny electronic components in microelectronic circuits, simply because the tiny objects are too small. A resistance value of a tiny object measured by a conventional four-wire milliohmmeter may be erroneous.

Therefore, an improved four-wire milliohmmeter is needed to overcome the described limitations.

### BRIEF DESCRIPTION OF THE DRAWINGS

FIG. 1 is an assembled, isometric view of a four-wire milliohmmeter in accordance with an exemplary embodiment.

FIG. 2 is an enlarged view of a circled portion II of FIG. 1.

### DETAILED DESCRIPTION

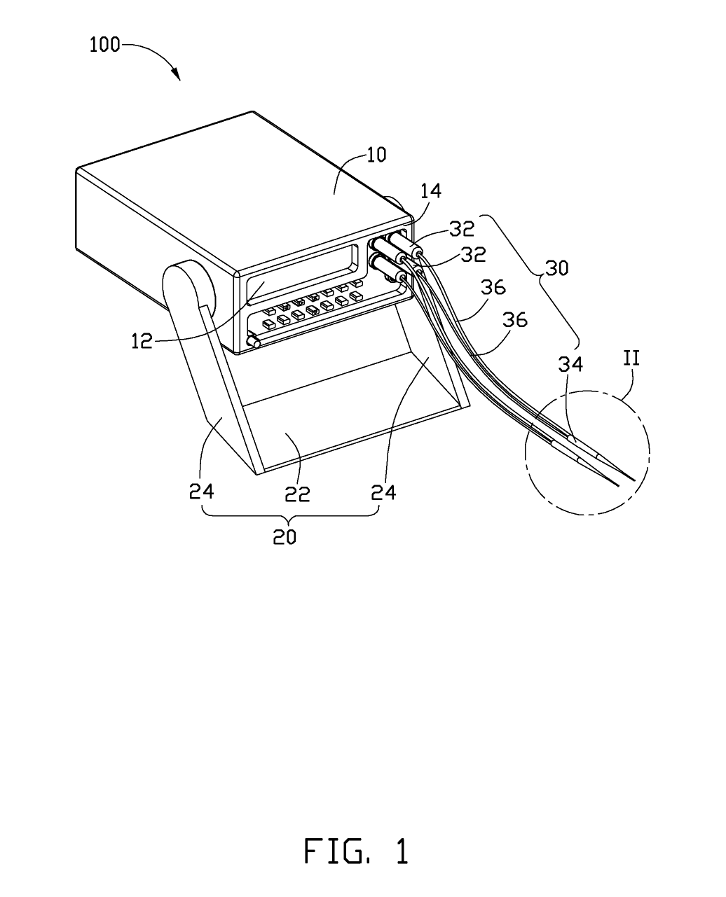

FIG. 1 shows a four-wire milliohmmeter 100 according to an exemplary embodiment of the disclosure. The four-wire milliohmeter 100 includes a main body 10, a support frame 20 connected with a front end of the main body 10, and two probe assemblies 30 electrically connected with the main body 10.

The main body 10 is substantially rectangular. A screen 12 is formed in a front side of the main body 10, to show the data measured by the four-wire milliohmmeter 100. The main body 10 forms two pairs of sockets 14 on the front side, beside the screen 12. Each pair of sockets 14 has the two sockets 14 arranged one above the other. Each pair of sockets 14 is engagable with one probe assembly 30.

The support frame 20 is substantially U-shaped. The support frame 20 includes a support portion 22, and two mounting portions 24 extending from two ends of the support portion 22. The mounting portions 24 are rotatably connected with right and left sides of the main body 10, respectively. A height of the front side of the main body 10 above a supporting surface such as a worktable can be adjusted by rotating the support frame 20, for users to conveniently read data displayed on the screen 12.

The probe assemblies 30 are the same. Each of the probe assemblies 30 includes two plugs 32, a contact member 34, and two wires 36 each connecting one of the two plugs 32 to the contact member 34. The plugs 32 of one probe assembly 30 are inserted into one pair of sockets 14 to electrically connect the probe assembly 30 to the main body 10. The plugs 32 of the other probe assembly 30 are inserted into the other pair of sockets 14 to electrically connect the other probe assembly 30 to the main body 10.

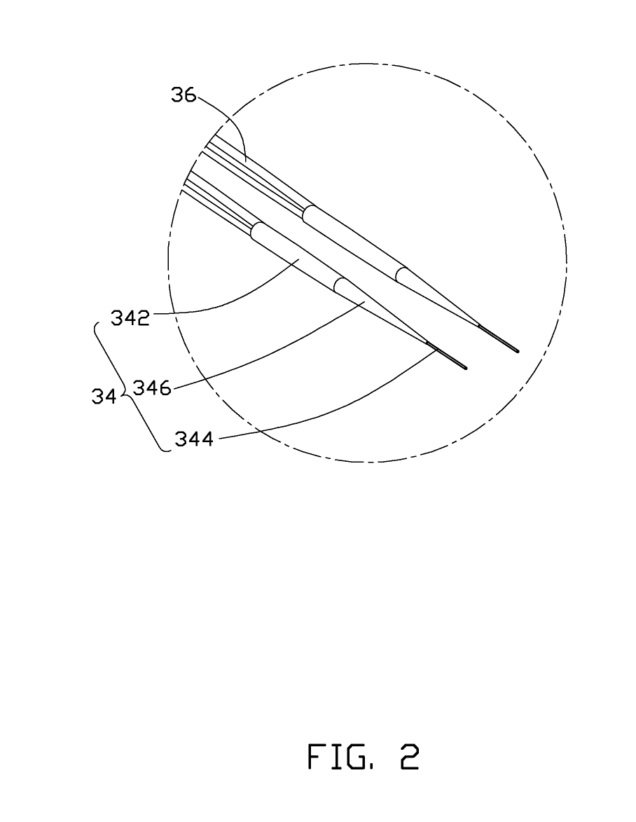

Referring to FIG. 2, the contact member 34 includes a handle portion 342 connected with the wires 36, a contact pin (or probe) 344, and a connecting portion 346 connected between the handle portion 342 and the contact pin 344. The connecting portion 346 and the contact pin 344 are both made of metal with good electrical conductivity.

The handle portion 342 is used for facilitating operation by users. The handle portion 342 is substantially column-shaped, and has a conductor (not shown) received therein for electrically connecting the connecting portion 346 to the wires 36. Thus, the connecting portion 346 is electrically connected with the main body 10, and the contact pin 344 is also electrically connected with the main body 10.

The connecting portion 346 is substantially conical, with a transverse cross section thereof gradually decreasing from the handle portion 342 to the contact pin 344. The contact pin 344 is needlelike and very sharp. The contact pin 344 includes a fixed end connected with the connecting portion 346, and a free end. A transverse cross section of the free end of the contact pin 344 has an area in the range of from approximately 0.05 mm² (square millimeters) to approximately 0.20 mm².

During operation, the contact pins 344 of the probe assemblies 30 are positioned to contact a component under test. One plug 32 of one probe assembly 30 and one plug 32 of the other probe assembly 30 are electrically connected with the main body 10, to form a current measuring circuit to measure a current of the component. The other plug 32 of the one probe assembly 30 and the other plug 32 of the other probe assembly 30 are electrically connected with the main body 10, to form a voltage measuring circuit to measure a voltage of the component. Then the four-wire milliohmmeter 100 calculates the resistance value of the component according to the voltage and the current, and data representing the resistance value of the component can be read on the screen 12.

Because the contact pin 344 of the probe assembly 30 is so sharp that the contact pin 344 is able to contact very small components, the measurement of the four-wire milliohmmeter 100 is more precise. The four-wire milliohmmeter 100 can be used in microelectronic fields, such as computer fields, communication fields, and consumer electronics fields. The four-wire milliohmmeter 100 can measure the resistance of HDIs (High Density Interconnections) of circuit boards in servers, desktop computers, notebooks, storage devices, workstations, DVD (Digital Video Disc) players, projectors, LCD TVs (liquid crystal display televisions), mobile telephones, cameras, etc.

It is to be understood, however, that even though numerous characteristics and advantages of certain embodiment(s) have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A four-wire milliohmmeter, comprising:
a main body; and
two probe assemblies electrically connected with the main body, each of the probe assemblies comprising two plugs detachably inserted into the main body, a contact member, and two wires each electrically connecting one of the plugs to the contact member, the contact member having a needlelike free end for contacting an object.

2. The four-wire milliohmmeter of claim 1, wherein the contact member comprises a handle portion electrically connected with the wires, a contact pin, and a connecting portion electrically connected between the contact pin and the handle portion.

3. The four-wire milliohmmeter of claim 2, wherein the handle portion is substantially column-shaped.

4. The four-wire milliohmmeter of claim 3, wherein the connecting portion is substantially conical, with a transverse cross section thereof gradually decreasing from the handle portion to the contact pin.

5. The four-wire milliohmmeter of claim 4, wherein the connecting portion is metal.

6. The four-wire milliohmmeter of claim 2, wherein a transverse cross section of a distal end of the contact pin has an area in the range of from approximately 0.05 mm² to approximately 0.20 mm².

7. A four-wire milliohmmeter, comprising:
a main body; and
two probe assemblies electrically connected with the main body, each of the probe assemblies comprising two plugs detachably insertable into the main body, a contact member, and two wires each electrically connecting one of the plugs to the contact member, the contact member being elongated, and a transverse cross section of a distal end of the contact member having an area in the range of from approximately 0.05 mm² to approximately 0.20 mm².

8. The four-wire milliohmmeter of claim 7, wherein the contact member comprises a handle portion electrically connected with the wires, a contact pin, and a connecting portion electrically connected between the contact pin and the handle portion.

9. The four-wire milliohmmeter of claim 8, wherein the handle portion is substantially column-shaped.

10. The four-wire milliohmmeter of claim 9, wherein the connecting portion is substantially conical, with a transverse cross section gradually decreasing from the handle portion to the contact pin.

11. The four-wire milliohmmeter of claim 10, wherein the connecting portion is metal.

12. A probe assembly for a four-wire milliohmmeter, the probe assembly comprising:
two electrical plugs configured for detachably engaging with the four-wire milliohmmeter;
a contact member having a needlelike free end; and
two wires each electrically connecting one of the plugs to the contact member.

13. The probe assembly of claim 12, wherein the contact member comprises a handle portion electrically connected with the wires, a contact pin, and a connecting portion electrically connected between the contact pin and the handle portion.

14. The probe assembly of claim 13, wherein the handle portion is substantially column-shaped.

15. The probe assembly of claim 14, wherein the connecting portion is substantially conical, with a transverse cross section gradually decreasing from the handle portion to the contact pin.

16. The probe assembly of claim 15, wherein the connecting portion is metal.

17. The probe assembly of claim 13, wherein a cross section of a distal end of the contact pin has an area in the range of from approximately 0.05 mm² to approximately 0.20 mm².
